(19) United States
(12) Patent Application Publication
(10) Pub. No.: US 2009/0034355 A1
(43) Pub. Date: Feb. 5, 2009

(54) INTEGRATED CIRCUIT INCLUDING MEMORY CELLS WITH TUNNEL FET AS SELECTION TRANSISTOR

(75) Inventor: Peng-Fei Wang, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/830,433

(22) Filed: Jul. 30, 2007

(51) Int. Cl. G11C 8/00; H01L 21/82

(52) U.S. Cl. 365/230.01; 438/128; 257/E21.602

(57) ABSTRACT

An integrated circuit having an array of memory cells is disclosed. One embodiment provides selection transistors for selecting one of a plurality of memory cells. The selection transistor is a tunnel field effect transistor in order to reduce a leakage current when the transistor is in its non-conducting state. Furthermore an operation method and a method for production are described.

### BACKGROUND

The invention relates to an integrated circuit. In one embodiment, the integrated circuit includes an array of memory cells with tunnel field effect transistors (TFETs) as selection transistors for selecting one of a plurality of resistively switching memory cells and a corresponding method of operation and fabrication.

Resistively switching memory cells are based on a reversible change of the resistance of an active or switching active material comprised in the cell. The change of the resistivity of a cell is induced by applying current to the switching active material. Examples of resistively switching memory cells are phase change (PC) memories, magneto resistive RAM (MRAM), conducting bridge (CB) memories using metal-doped chalcogenides, transition metal oxide resistive change RAM (TMO RRAM) employing materials like NiOₓ, TiOₓ, HfOₓ, ZrOₓ or oxides of perovskite type.

In a memory device including a plurality of memory cells, the afore described cells usually are arranged in a 1T1R order, that is one transistor is assigned to one resistively switching memory cell for selecting the cell. The most common arrangement is to couple one electrode of the memory cell to a bitline and the residual electrode to the drain of the selection transistor, while the source of the selection transistor is coupled to a reference voltage, referred to as ground. As the gates of selection transistors are coupled to wordlines, a memory cell can be selected by selecting the corresponding pair of bitline and wordline.

An ever-challenging problem is to reduce the size and the manufacturing costs of semiconductor circuits while at the same time improving the capabilities.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic circuit diagram of a volume of phase change material and an appendant selection transistor.

FIG. 2a, b illustrates an integrated circuit including a schematic circuit diagram of an array of memory cells and a schematic of a corresponding layout.

FIG. 3a-c illustrates a top view and cross sectional views through a selection transistor.

FIGS. 4a, b illustrate cross sectional views through memory cells.

FIGS. 5a-c illustrate views of cells in a first production process.

FIGS. 6a-c illustrate views of cells in a later production process.

FIGS. 7a-c illustrate views of cells in a further production process.

FIGS. 8a-c illustrate views of cells in a later processing process

FIG. 9 illustrates a view of memory cells.

FIGS. 10a-c illustrate views of memory cells in an early production stage.

FIGS. 11a-c illustrate views of memory cells in a later production stage.

FIGS. 12a, b illustrate views of cells in a further production stage.

FIG. 13 illustrates a cross sectional view of produced memory cells.

FIGS. 14a-c illustrate views of cells having a planar TFET in an early production stage.

FIG. 15 illustrates a cross sectional view of produced cells with a planar TFET.

FIG. 16 illustrates a cross sectional view of produced cells with a different arrangement of the phase change material.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

In phase change memories the resistance changes due to an amorphous-crystalline phase transition of the phase change material being the switching active material. The phase change materials include the family of chalcogenide compounds, for example the commonly used GeSbTe or AgInSbTe. The resistance of the switching active material in the crystalline state differs significantly from the resistance of the material in the amorphous state. A logic bit can be assigned to a cell, wherein a first logical state of the bit can be assigned to the conducting/less resistive state and the second logical state of the bit can be assigned to the less conducting/resistive state of the phase change memory cell. Reading the cell, i.e. by determining its resistance, can retrieve the value of the bit. For writing a bit value assigned to the conducting/less resistive state to the cell, i.e. to transform the phase change material to crystalline, a current pulse is sent through the switching active material to heat the material over its crystallization temperature thus lowering its resistance. For resetting a phase change memory cell to the less conducting/more resistive state a comparatively strong current pulse is sent through the phase change material for heating and causing the switching material to melt, which is subsequently forced into the amorphous state by quench cooling the material.

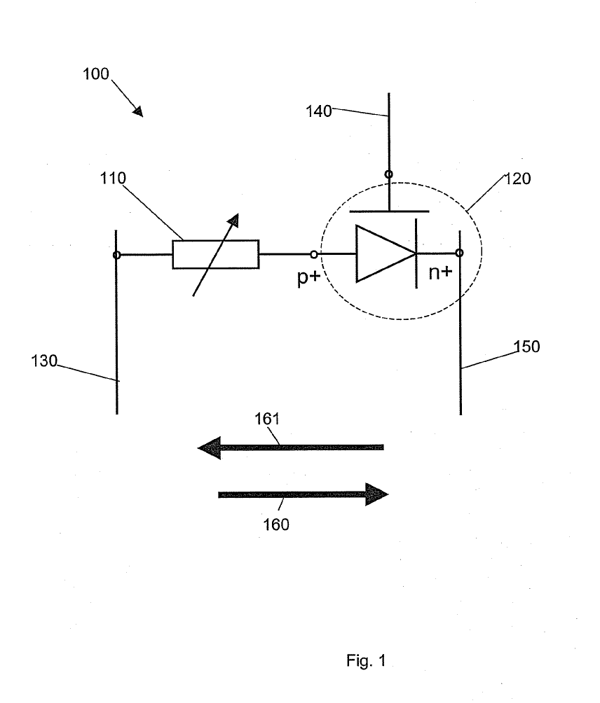

FIG. 1 illustrates an electrical circuit 100 illustrating a volume of phase change material 110 coupled to a tunnel field effect transistor 120 (TFET) as selection device. The volume of phase change material 110 is coupled with its one end to a source word line 130 and to the TFET 120 with its other end.

Note that in the following description the source areas of the described transistors are of a first doping type, which in the embodiments is n+, and drain areas are of a second doping type being p+ in the examples. The doping types may be exchanged, i.e. opposite doping types may be used and the direction of the MOS-gated pin-diode may be changed accordingly.

TFET 120 is illustrated as a diode having a gate, because the structure of the TFET is based on a MOS-gated pin-diode with the drain separated from the source by an intrinsic layer having a very low doping or none. In normal operation and without a biasing gate voltage, a current flows from source to drain, i.e. in diode direction, if a voltage higher than the ON voltage of the diode is applied from source to drain. The gate is arranged to effectuate an electrical field to the intrinsic layer causing the tunneling of charge carriers. That is, if a bias voltage is applied to the gate an electron channel is induced, such that a current may flow against the diode direction. Once the channel charge concentration is decreased, a tunneling junction is formed at the source side of the diode, i.e. at the p+ area. Accordingly the TFET is conducting in the direction against the illustrated diode direction if a bias is applied to the gate. For the non-conducting TFET, i.e. if the gate is not biased, there is a barrier between source and drain in the direction against the diode, enabling very small leakage currents, whereas in diode direction the TFET illustrates properties of a PIN diode, such that large currents are possible in this direction.

Accordingly for setting the state of phase change material, i.e. changing the state of the phase change material from the amorphous to the crystalline state the highest current is needed, a voltage is applied to the p+ area, i.e. the source word line 130, while the gate bias applied via gate word line 140 and the voltage at the n+ area applied via bit line 150 are maintained at 0 Volts. A corresponding high current will then flow into the direction of the diode as indicated by arrow 160. When resetting the volume of phase change material, i.e. when an even higher current is needed, a resetting voltage can be applied to the p+ area and a zero voltage can be applied to the n+ area while a gate bias is applied to the gate, such that the current flowing in the direction as indicated by arrow 160 is even higher because of the increased conductivity due to the additional tunneling effect. Values of the setting and resetting voltage may be 4.0 Volts and the resetting gate bias may be 2.7 Volts.

When reading or selecting a cell, i.e. when a smaller current can be applied for sensing the conductivity of the volume of phase change material, a gate bias can be applied to the gate and a reading voltage is applied to the n+ area, while the p+ area is maintained at a zero voltage. Due to the tunneling effect a current will flow against the diode direction, i.e. as indicated by arrow 161, wherein the current is much smaller than the set/reset current. An exemplary value of the reading voltage may be 1.8 Volts.

In idle state, the gate bias and the voltage applied to the p+ area are maintained at 0 Volts and the voltage applied to the n+ area can be for example in the range between 0 Volts an 4 Volts.

So when writing the cell, i.e. when setting or resetting the volume of phase change material, a voltage from source (p+ area) to drain (n+ area) is applied, such that a strong current flows in a first direction, namely in the diode forward-bias direction, and wherein the gate of the TFET, which is coupled to the gate word line 140 can be biased optionally to increase the current for resetting the cell.

When reading the cell, i.e. when sensing the resistivity/conductivity of the cell, a voltage from drain to source and a gate voltage for inducing the tunneling junction are applied, such that a small current flows in a direction opposite to that when writing the cell, i.e. against the diode direction.

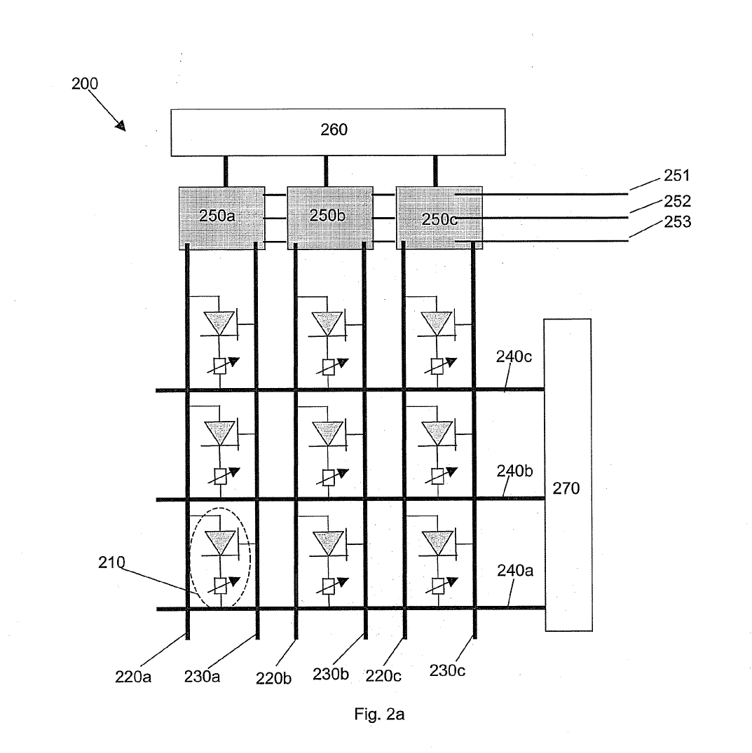

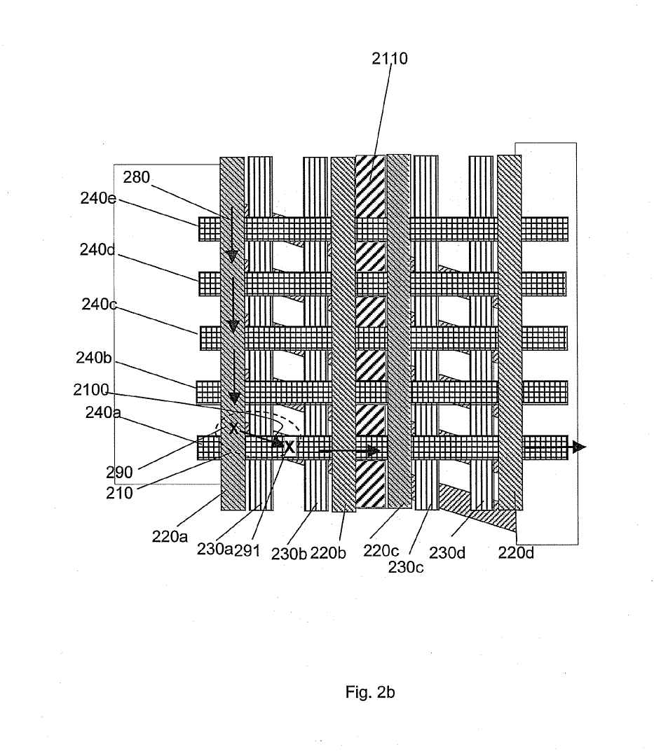

Circuit 200 as illustrated in FIG. 2a illustrates a circuit 200 exemplifying an integrated circuit including an array of memory cells, wherein cells are coupled to source and gate word lines 220, 230 and bit lines 240. For example memory cell 210 is coupled to a source word line 220a and a gate word line 230a and a bit line 240a.

Each pair of word lines, wherein a pair includes one source word line and one gate word line, and which are coupled to a column of memory cells, is controlled by a logic block 250, which in turn is coupled to an Y-decoder 260 for enabling a logic block and furthermore to line 251 for mode toggling between write, i.e. set/reset mode, and read mode, i.e. sense mode, and furthermore to a first voltage supply line 252 providing the required setting, resetting and reading voltages.

The bit lines 240a to 240c are connected to an X-decoder 270 for providing and processing the bit line signals.

In operation, for example when operating on memory cell 210, the Y-decoder 260 enables block 250a such that this block can apply voltages to lines 220a and 230a and the X-decoder 270. When writing cell 210, i.e. when a high current shall flow through cell 210 for setting or resetting, line 251 is set to ON. Logic block 250 will accordingly multiplex the voltage of line 252 to source word line 220a and ground/reference potential to gate word line 230a. When reading cell 210, line 251 will be set to OFF and block 250a will provide ground potential to the source word line 220a and the voltage of line 253, i.e. the bias voltage, to the gate word line, such that, assuming that the voltage of the bit line 240a is set to an appropriate voltage, a small current will flow from bit line 240a to source word line 220a. According to the mode signal on line 251 block 250a will apply either a setting or resetting voltage or a zero voltage to source word line 220a and the bias voltage or a zero voltage to gate word line 230a, if selected by an appropriate signal from Y-decoder 260, such that block 250a toggles the voltages of the word lines corresponding to the operation mode indicated by line 251.

FIG. 2b illustrates an embodiment of a layout of the source word lines 220a-220d, gate word lines 230a-230d and bit lines 240a-240e. When writing for example cell 210 as encircled by the dotted oval, a setting or resetting voltage is applied to source word line 220a. A current as illustrated by arrows 280 will leave source word line 220a and flow through the source of the selection transistor, wherein the source may be located as indicated by the X 290 and beneath the source word line 220a. The current will then flow through an active area 2100 extending beneath gate word line 230a and will enter bit line 240a via the drain, which is located as indicated by the X 291 and beneath bit line 240a.

As will be also illustrated in more detail in the following figures the source word lines 220a-220d are the top most lines, the gate word lines 230a-230d are the lowermost lines and the bit lines 240a-240e are arranged in a level between the source word lines and the gate word lines, wherein the regions of the active areas 2100 are arranged beneath the gate word lines. As the source word lines are arranged above the gate word lines, the source word lines may overlap the gate word lines.

The source word lines are arranged in parallel to the gate word lines, and the bit lines are arranged rectangular to the word lines. Note that the active areas in this embodiment are arranged tilted with respect to the word lines and bit lines respectfully.

Note that between source word lines 220b and 220c there is an insulating trench 2110 or an insulating device separating a first group of cells including word lines 220a and 220b from a second group of cells including source word lines 220c and 220d. The insulating trench may be formed from any dielectric, for example silicon oxide. Accordingly there are no active areas between source lines 220b and 220c.

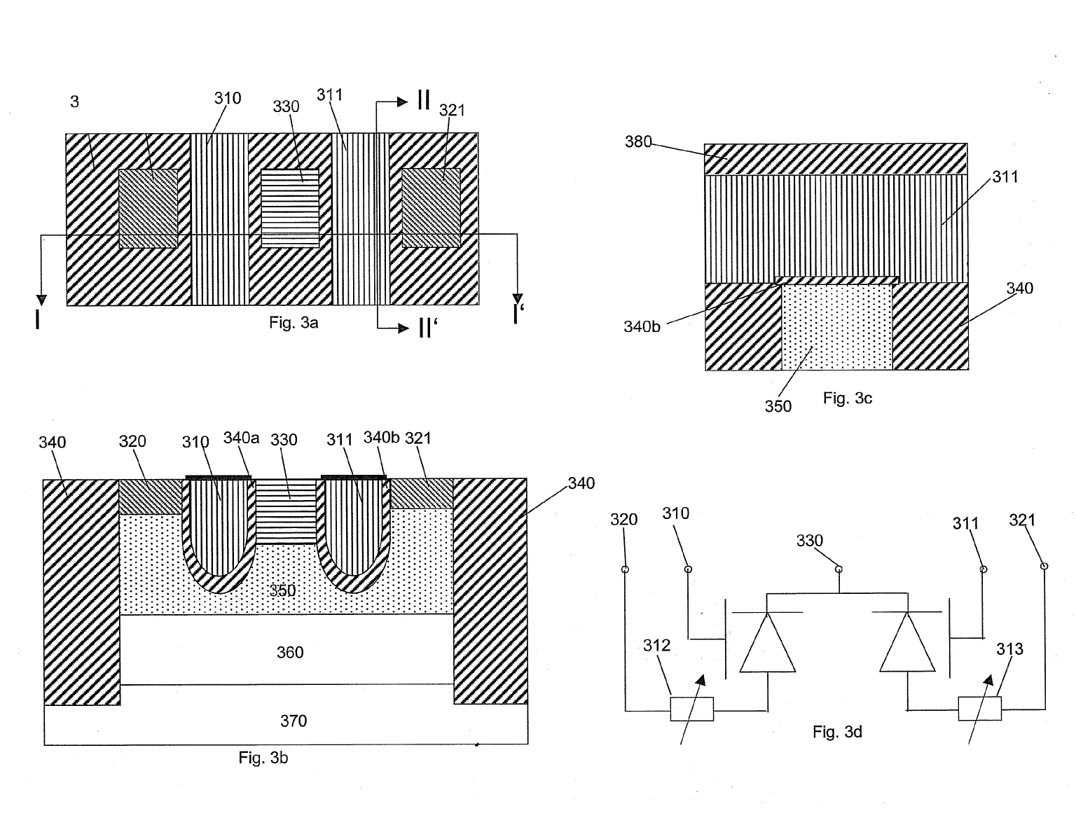

FIGS. 3a to 3d schematically illustrate a layout and a corresponding device sketch of two tunnel field effect transistors with recessed channels.

FIG. 3a illustrates a top view on a layout of two TFETs, wherein the cut line is parallel to the original surface of the wafer or substrate, the original surface of the substrate thus forming a reference plane. Gate conductors 310 and 311 form the gates of a plurality of TFETs and also form gate word lines. Source word lines will be described later. As mentioned above a TFET can be seen as a gated PIN diode. P+ areas 320 and 321 form the source of two PIN diodes and the n+ area 330 forms the drain of both PIN diodes. That is in this structure two TFETs share a common n+ area, such that the two TFETs share one drain 330. While the p+ and n+ areas are demarcated areas surrounded by any dielectric 340, the gate conductor lines 310 and 311 form lines coupling to a plurality of TFETs located along the gate conductor lines.

FIG. 3b illustrates a cross section along cut line I-I′. The p+ areas 320, 321 and also the n+ are closer to the substrate surface than the gate oxide 340a, 340b, i.e. the gate oxide 340a, 340b and the gate conductor lines extend deeper into the intrinsic or weakly doped layer 350, which will take the conducting channel. Accordingly the conducting channel in either direction, i.e. either from the source to the drain in case when setting or resetting a cell or from the shared drain to a source when reading/sensing the cell is curved around the gate oxide 340a or 340b respectively. The length of a conducting channel is thus determined by the dimensions of the corresponding gate conductor 310, 311 and its surrounding gate oxide layer 340a and 340b respectively, i.e. the length of the conducting channel depends on the width and the depth of the gate conductor and its gate oxide layer.

Shallow trench isolation 340, which may be any dielectric like for example silicon oxide, delimits the active area in direction perpendicular to the gate conductor lines, such that the device is electrically isolated from adjacent devices.

Sources 320 and 321 are p+ doped such that they have an abrupt junction to the neighboring active area 350, whereas drain 330 is n+ doped having a soft junction to active area 350. That is the p+ doped source/drain regions have a first transition region to the adjoining intrinsically conducting region and the n+ doped shared drain/source region has a second transition region to the adjoining intrinsically conducting region, wherein the width of the first transition region is smaller that the width of the second transition region.

Layer 360 arranged below the n− doped layer 350 forming the active area may be of any non-conducting material, i.e. this may be a p− or n− doped layer or an oxide. Layer 370 arranged below layer 360 may be any material, for example native Si or well material or a non-conducting oxide or an n− or p− doped material.

FIG. 3c illustrates a cross sectional view along cut line II-II′ running through gate conductor line 311.

In this view gate the conductor line 311 is covered by an insulating layer 380, which may be of any dielectric. This dielectric layer 380 indicates that the gate conductor line may be buried, i.e. the gate conductor line may be arranged below the original surface of the substrate, which can be achieved by forming a deep enough trench for gate conductor line 311, which takes the gate conductor line completely. Note that it is optional to form buried gate conductor lines.

Gate conductor line 311 is isolated by a gate oxide layer 340b from active area 350, which is delimited by dielectric 340 in the direction of the gate conductor line 311. Active area 350 is thus delimited in direction of gate conductor and perpendicular to that direction by dielectric 340.

FIG. 3d illustrates a device sketch of the arrangement illustrated in FIGS. 3a-3c. The sources of the diodes are formed by p+ doped areas 320, 321 having an abrupt doping junction to active area 350, which in turn couples to the n+ doped area 330 being the drain of the diode. Variable resistors 312 and 313 illustrate the variable resistance of the diodes, as the resistance of the diode may vary depending on a bias voltage applied to the gate. The intrinsic conducting layer 350, which is typical for a TFET transistor, is not explicitly illustrated in this device sketch. However it is implicitly disclosed as gate conductors 310 and 311 are the gates of the TFETs.

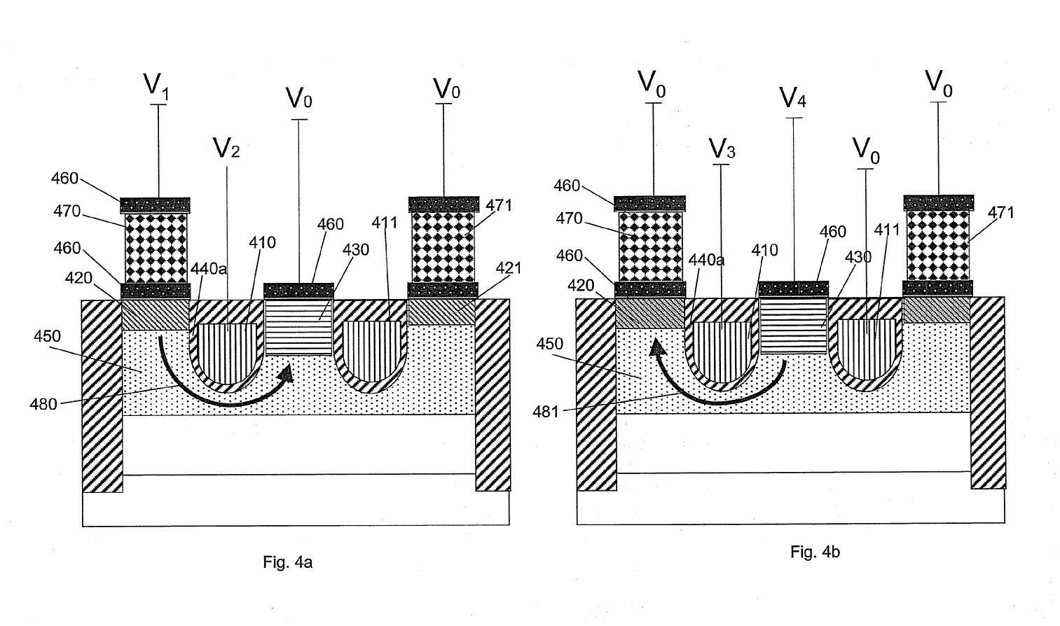

FIGS. 4a and 4b schematically illustrate the arrangement of two phase change RAM cells with a tunnel field effect transistor (TFET) as selection or array transistor and a volume of phase change material coupled to a transistor.

FIG. 4a illustrates a situation when writing the cell on the left side of the drawing. The TFET on the left side includes source 420, drain 430 and an intrinsic conducting layer 450 forming an active area between source and drain and a gate conductor 410 isolated by gate oxide 440a from active area 450. Source 420 is coupled by a conductor 460, which forms a bottom electrode contact, to a volume of phase change material 470, which in turn is coupled via a top electrode contact 460 to a source word line not illustrated in this drawing.

Note that in this embodiment gate conductor line 410 is covered by a dielectric layer, such that in contrast to the previously illustrated architecture the top of gate conductor 410 is located lower than the top of source 420 or drain 430.

The voltages V0, V1 and V2 as illustrated in the drawing can be applied in order to set or reset the cell, i.e. in order to send a strong current through the volume of phase change material. The values of the voltages are examples giving the approximate values of the voltages. Accordingly the setting or resetting voltage V1 can be applied to top electrode contact 480 and a voltage V0 of 0 Volts, i.e. no voltage with reference to a reference potential, can be applied to drain 430 for example via an electrode contact 460 located on top of drain 430. In this way the PIN diode formed by source 420, intrinsic layer 450 and drain 430 is operated in its conducting direction causing a strong current flowing from source 420 through the intrinsic layer 450 to drain 430 as indicated by arrow 480, wherein the current also flows through the volume of phase change material 470.

As the PIN diode is operated in its conducting direction the gate voltage may be maintained at V2=0 Volts or may be set for example to a higher voltage, wherein the bias voltage effectuates a tunnel in intrinsic layer 450 increasing the conductivity in the conducting channel thus increasing the amplitude of the current.

While setting/resetting the memory cell on the left hand side the cell on the right hand side, i.e. the cell including phase change material 471 shall be kept unchanged. A current flow through the cell on the right side of FIG. 4a is prevented by the PIN diode formed by source 421, intrinsic layer 450 and drain 430, because this diode blocks any current in direction to phase change element 471.

FIG. 4b illustrates the same architecture as illustrated in FIG. 4a but when reading the cell including phase change material 470.

For reading the cell, i.e. for sensing whether resistivity of phase change material 470 is high or low, the reading voltage V4 is applied to drain 430, a zero voltage V0 is applied to the top electrode contact 460 of the phase change material 470 and the bias voltage V3 is applied to gate conductor line 410. The applied gate voltage effectuates the tunneling of electrons from the source to the drain, such that a current is flowing from drain 430 to source 420 as indicated by arrow 481. By applying a gate voltage V3 the blocking of the PIN diode is nullified. However the conductivity of the tunnel allows a current of smaller amplitude, such that the amplitude of the current as indicated by arrow 481 is smaller than the current in diode direction, but wherein the smaller current is sufficient to sense the resistivity of the phase change material 470.

In this operation the state of phase change material 470 shall be sensed only. Accordingly, a zero voltage V0 is applied to gate conductor 411 so that there will be no tunneling effect in this direction and the PIN diode of the right cell blocks any current from flowing through this cell.

The described schematics of a phase change RAM cell with a tunnel field effect transistor can be implemented in various architectures as described in the following.

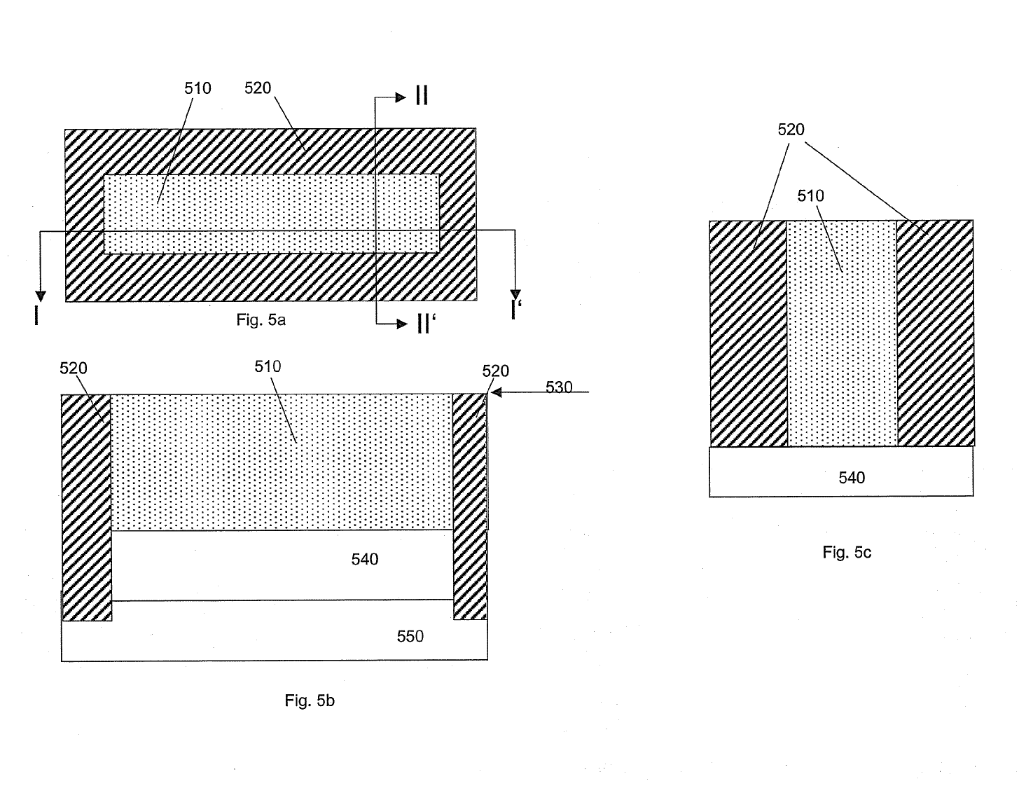

FIGS. 5 to 9 schematically illustrate an embodiment of processes for producing a PC RAM cell including a TFET transistor as selection transistor, wherein the transistor includes a recessed channel and the gate conductor, i.e. the gate word line, is located below the surface of the wafer, the gate conductor thus being buried.

Although the figures are not drawn to scale they illustrate the relative arrangement of areas and elements to each other, in particular which elements are adjacent and which element is on top of another.

FIGS. 5a to 5c illustrate a first stage of the manufacturing process. Note that this production stage is common to all subsequent described embodiments of the invention. Hence this stage will be described only once.

FIG. 5a illustrates a top view on a substrate surface wherein a first region of intrinsic conducting, n+ doped material 510, which will form the active area of the selection transistor, is delimited by a dielectric 520. The n+ doped, intrinsic conducting material for example may be n+ doped silicon and the dielectric may be silicon oxide.

FIG. 5b illustrates a cross section along cut line I-I′, which is perpendicular to the gate conductor line produced in later processes. The surface of the original substrate is denoted by arrow 530.

Dielectric 520 and the n+ doped layer 510 are arranged on an insulating layer, which may be any insulating material e.g., silicon oxide 540, such that the layers are arranged as silicon-on-insulator SOI, wherein insulating layer 540 may be arranged on any n− or p− doped or an insulating oxide layer or the original substrate of the chip. Dielectric 520 furthermore extends deeper into layer 540 or layer 550. Accordingly the intrinsic area 510 is an electrically closed area.

FIG. 5c illustrates a cross section along cut line II-II′, which is parallel to the gate conductors produced in later processes. The weakly doped or intrinsic conducting layer 510 is delimited by the dielectric of the shallow trench isolation 520, which extends at least to layer 540 in order to decouple layer 510 from neighboring areas.

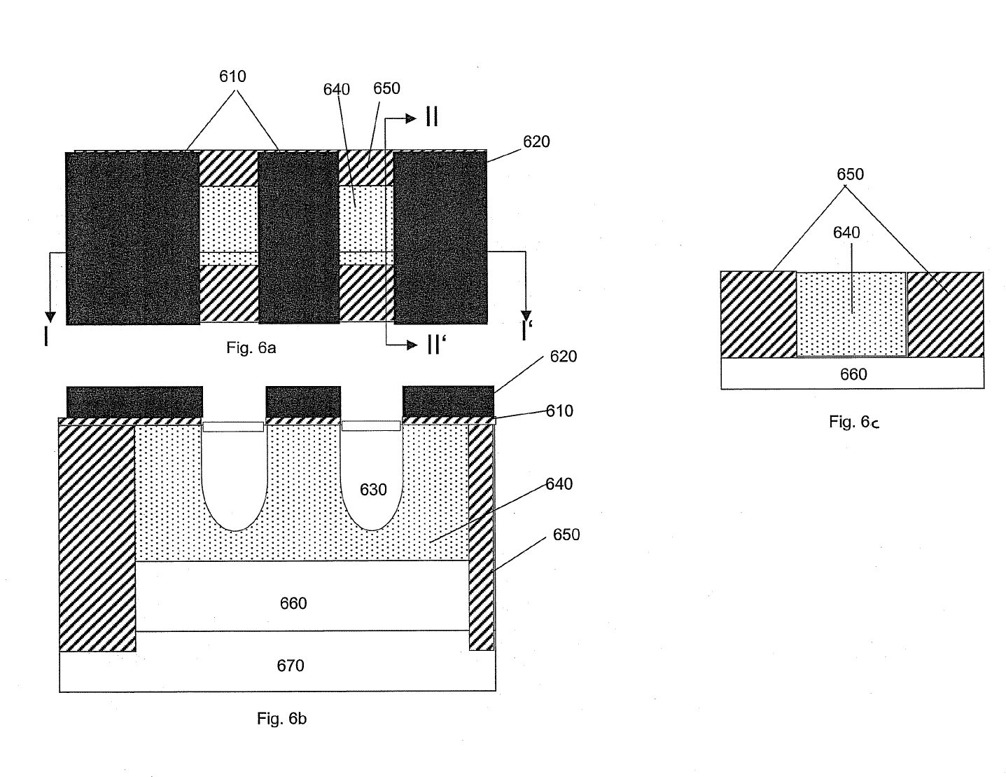

FIGS. 6a to 6c illustrate the later process of creating trenches, which will at least partially take the gate conductors, i.e. the gate word lines.

In FIG. 6a a sacrificial buffer layer 610 of dielectric material e.g., silicon oxide and a hardmask layer 620 have been deposited. As the hardmask layer 620 has been deposited on top of buffer layer 610, this is covered and therefore hidden. The buffer and the hardmask layers have been patterned by conventional lithographic processes to form the contour of the gate conductor trenches.

FIG. 6b illustrates a cross sectional view along cut line I-I′ after the recessed gate conductor trenches 630 have been etched. Note that in this exemplary embodiment the bottom of 630 trenches has been rounded to a corresponding rounded shape by an optional wet or dry isotropic etching process, such that the gate conductors will also have a rounded shape.

However the optional process of rounding the bottom of the trenches 630 may be omitted, such that the trenches have a flat bottom with sharp edges, which is not illustrated in the drawing.

FIG. 6c illustrates a cross sectional view along cut line II-II′ being parallel to and through a recessed gate conductor trench 630. Although the figures are not drawn as mentioned above the height of the intrinsic material 640 and of dielectric 650 in this view is decreased significantly when compared to FIG. 5c, because cut line II-II′ runs through the trench. Reference numerals 660, 670 denote an insulating layer and the substrate.

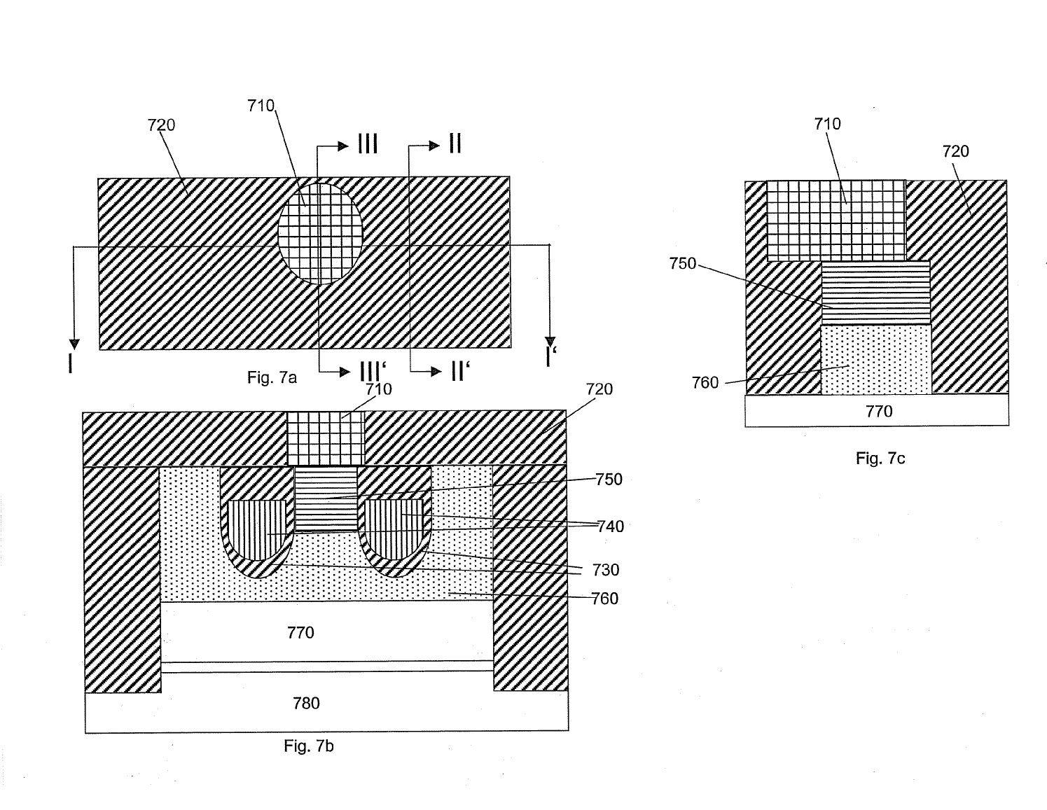

FIGS. 7a to 7c illustrate an embodiment of the chip at a later stage of processing after a source/drain and a connected bit line contact have been formed.

The top view on the chip as illustrated in FIG. 7a only illustrates a bit line contact 710 surrounded by dielectric 720, which covers the elements produced in the previous processes.

FIG. 7b illustrates a cross sectional view along cut line I-I′. After the trenches for the gate conductors have been formed the hard mask material is removed from the surface of the chip. After a pre-oxidation treatment, which may include a cleaning step, the silicon is oxidized to form gate oxide 730 in the trenches. Subsequently the gate conductor material which may be polysilicon or a metal such as tungsten or any suitable alloy is deposited and subsequently isotropically recessed to form gate conductor lines 740. Then a dielectric such as silicon oxide is deposited and etched back to insulate the topside of gate conductor lines 740.

Note that at the same time when performing these processes the support devices, i.e. the peripheral devices for controlling the array of memory cells, can be performed.

In a next process a dielectric layer is deposited, for example by using a low-pressure chemical vapor deposition method. The hole, which will form the bit line contact 710, may be etched by using conventional lithographic and etching processes. Once the hole is etched n+ type ions are implanted through the hole to form n+ area 750, which will in this embodiment form the shared drain/source for two adjacent TFET transistors, wherein the implantation processing is adjusted to form a doping profile with a soft or sharp junction to active area 760 located below the n+ doped drain/source area. Alternatively to implanting n+ ions a layer of n+ doped poly silicon may be deposited such that n+ ions diffuse into layer 760 to from a soft or sharp junction profile at the border to layer 760. Other doping techniques may also be used.

Reference numerals 770, 780 denote an insulating layer and the substrate of the chip.

After the n+ doped area has been produced the hole is filled with a conducting material such as polysilicon or any suitable metal, which is subsequently planarized for example by a conventional chemical-mechanical polishing process, to from bit line contact 710.

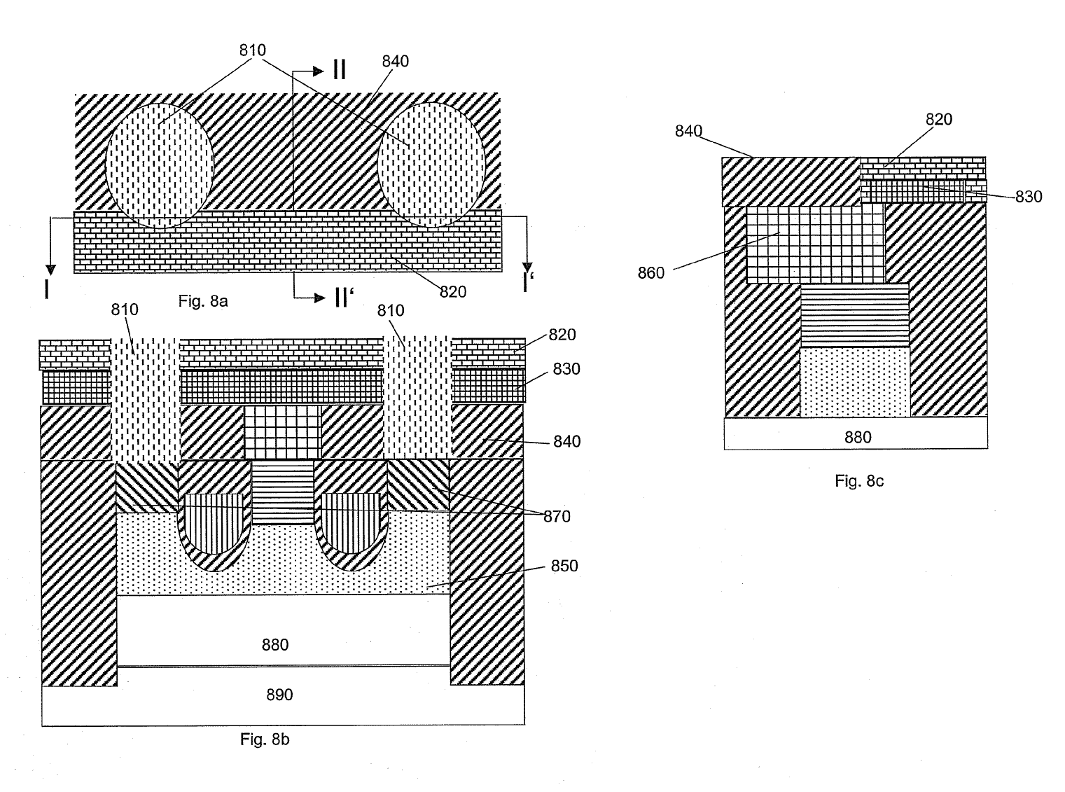

FIG. 8 illustrate an embodiment of the chip after a bit line and cell contacts have been formed.

FIG. 8a illustrates a top view on the chip showing cell node contacts 810 and an insulating cap 820 covering bit lines 830. Space between these elements is filled with dielectric 840.

After the planarization process as mentioned with regard to FIG. 7 the bit line material, i.e. any suitable conductor such as polysilicon or a metal or an alloy, is deposited and shaped to form bit line 830, which may be subsequently covered by a suitable insulator such as for example silicon nitride, wherein also insulating spacers may be formed at the bit line side wall. FIG. 8b illustrates a cross sectional view along cut line I-I′, which illustrates this architecture.

Then holes for the cell node contacts 810 are formed using lithographic and subsequent etching processes. When the holes are etched p+ type ions are implanted into the silicon at the bottom of the holes to form p+ doped source drain areas 870, wherein the implanting process is controlled to produce an abrupt ending doping profile, such that there is an abrupt doping borderline between source/drain area 870 and the adjacent intrinsic layer 850. Alternatively to performing such a high dose implantation p+ doped polysilicon can be deposited, from which ions will diffuse out or other doping techniques may be used.

Once the p+ doped source/drain areas 870 are produced the holes are filled with a suitable metal, e.g., tungsten or any suitable alloy, to from cell contacts 810, wherein the deposited metal layer is planarized to remove redundant metal from the chip surface.

Reference Numerals 880, 890 denote an insulating layer and the substrate respectively.

FIG. 8c illustrates a cross sectional view along cut line II-II′.

Once these process steps have been performed processing of the back-end can be performed producing volumes of phase change material coupled to the cell node contacts with their one end and to source word lines with their residual end.

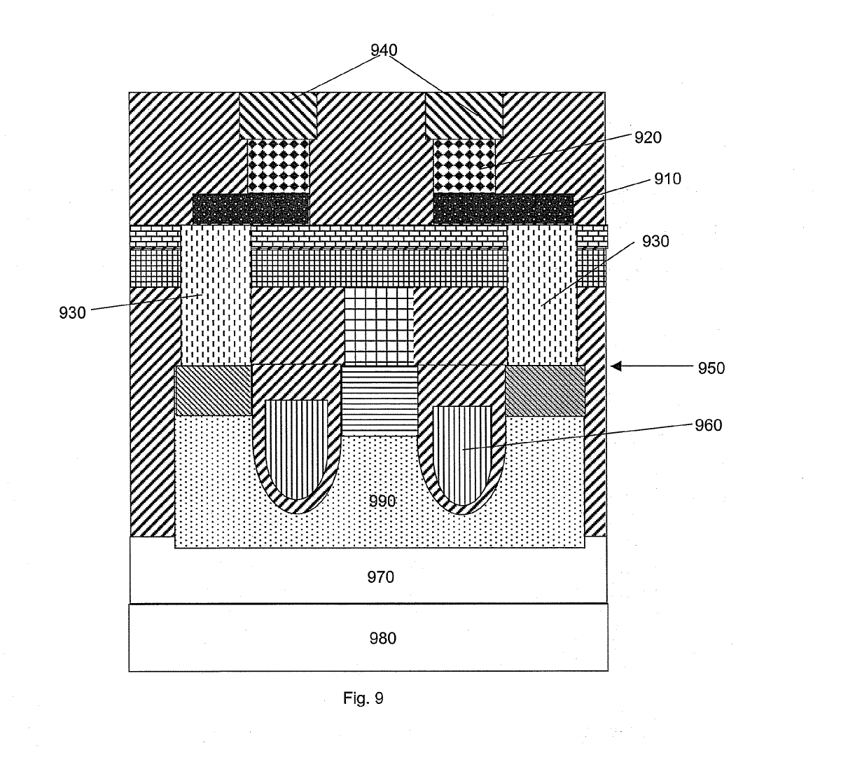

FIG. 9 illustrates a cross sectional view after the back end processing has been performed, in which bottom electrode contacts 910 have been formed to couple the volumes of phase change material 920 to the cell node contacts 930. The volumes of phase change material 920 couple with their other end to source word lines 940.

The source word lines 940 and gate word lines being the gate conductor lines 960 run in parallel, wherein in this exemplifying embodiment the source word lines are arranged above the surface of the original wafer or substrate as indicated by arrow 950 and the gate word lines are arranged below the reference plane. Reference numeral 990 denotes the intrinsic layer, in which the conducting channel is formed. Reference numerals 970 and 980 denote an insulating layer and the substrate respectively.

In a variation of the embodiment illustrated in FIG. 9 the phase change material may be formed in the cell node contacts 930. That is the phase change material is arranged in the holes etched for the cell nodes and is thus placed below or at the level of the bit line. Consequently source word lines 940 can be coupled directly to contacts 910, which would reduce the number of processes.

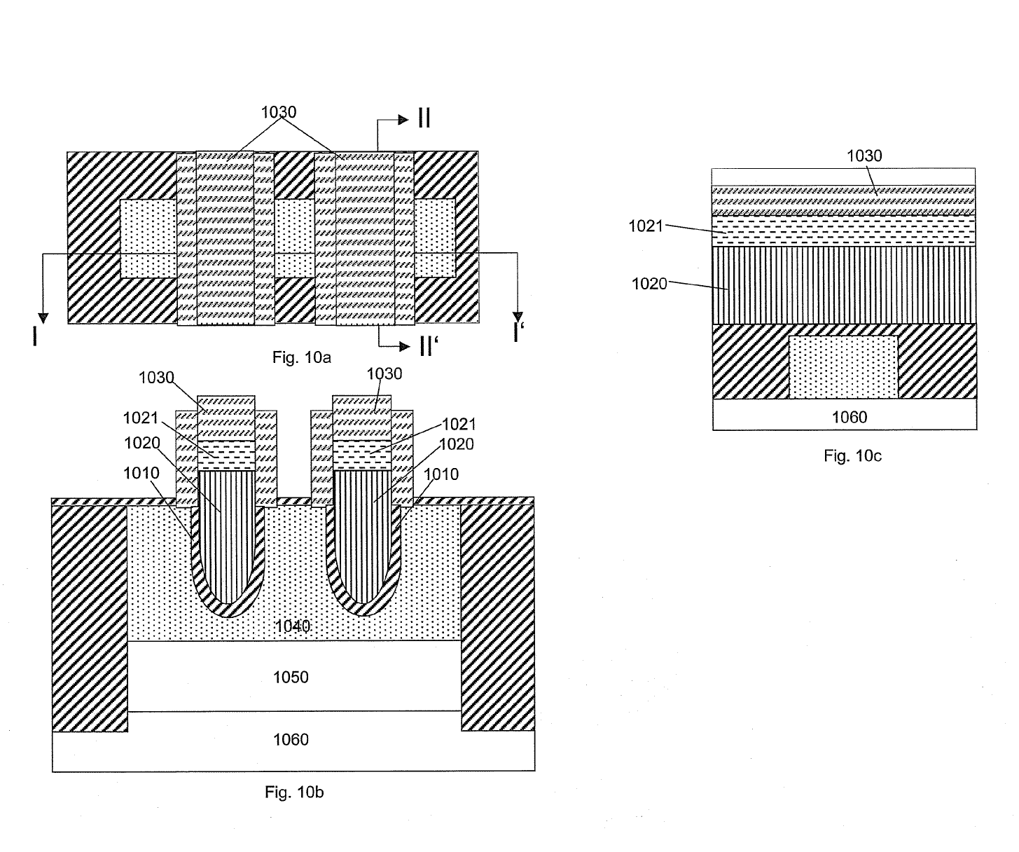

FIGS. 10 to 13 illustrate consecutive stages when producing a further embodiment including non-buried gate conductor lines, and for example a gate stack including a metal layer can be used.

In the beginning processes for this embodiment are identical to those described with reference to FIGS. 5 and 6. Accordingly the processing of described with reference to FIG. 10 assumes that these processes have been performed.

After the gate conductor trenches have been etched the hard mask material is stripped and a pre-oxidation preparation process is performed to clean the surface before the gate oxide 1010 is produced by performing e.g., a conventional oxidation step. Subsequently a gate conductor, i.e. a gate word line can be produced. The illustrated gate word line stack including a first and a second material layer 1020 and 1021 may serve as one example of a gate word line stack. Any word line stack architecture may be used which can be implemented in the recessed gate conductor trench, wherein part of the gate word line stack may extend into the trench. For example the first material layer may be poly silicon and the second material layer may be any suitable metal such as tungsten or an alloy such as titanium nitride. A gate word line stack in this way for example combines the property of poly silicon, which is easy to handle when filling trenches with the improved conductivity of a metal.

Once the gate conductor portion extending into the gate conductor trench is shaped into lines, an insulating cap 1030 for example of silicon nitride is produced. Reference numeral 1050 denotes an insulating layer insulating the intrinsic layer 1040 from the substrate 1060.

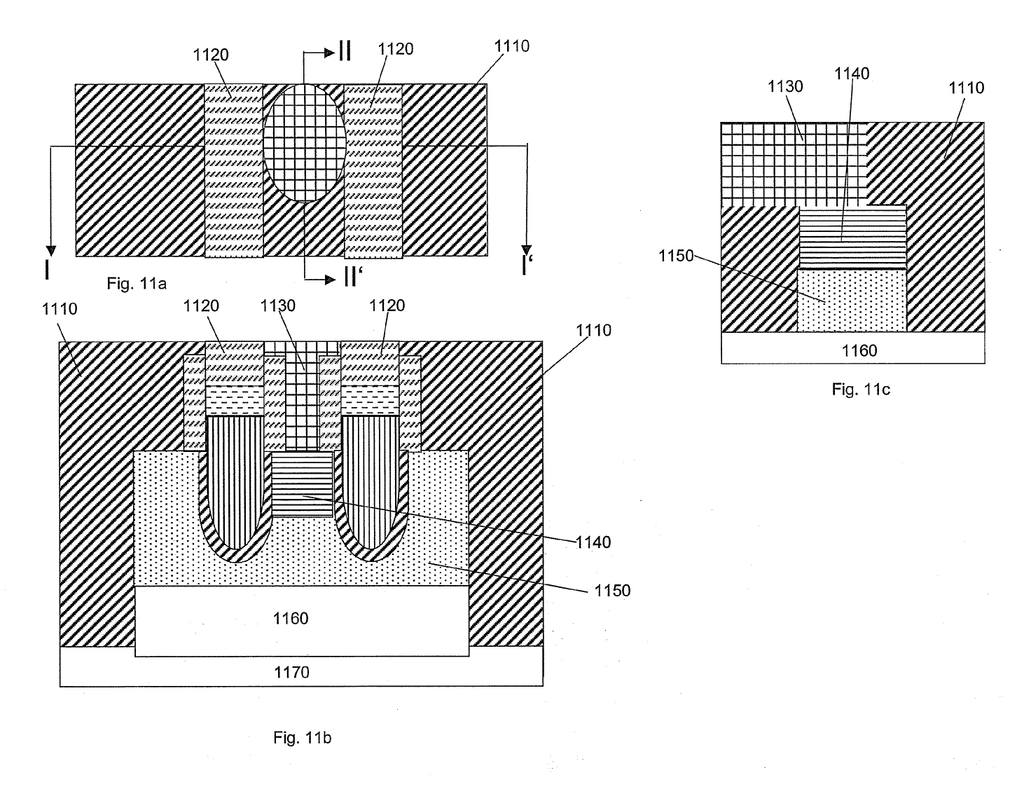

FIG. 11 illustrate an embodiment of integrated circuit after the shared drain/source of the selection transistors and a bit line contact have been produced.

After the gate conductor stack has been produced, a dielectric layer 1110, e.g., a TEOS layer, is deposited on the chip as a thick oxide layer, which is planarized with stop on the insulating SiNi cap 1120 of the gate conductor lines.

FIG. 11b illustrates a cross sectional view along cut line I-I′. For producing bit line contact 1130 a hole is etched between gate conductor stacks by using conventional lithographic and subsequent etching processes. After the hole is etched an n+ type high dose implant is performed to form the drain/source area 1140, which is the shared source/drain of the two selection transistors, wherein the doping profile is controlled to produce a junction to the underlying intrinsic layer 1150, which is insulated by an insulating layer 1160 from substrate 1170. Alternatively to the high dose implant an n+ doped polysilicon can be deposited, which will diffuse out. After area 1140 is produced the bit line contact material is deposited in the hole to from bit line contact 1130 and planarized with stop on cap 1120, wherein the contact material may be any suitable conductor such as a polysilicon or a metal like tungsten or an alloy like titanium nitrite.

FIG. 11c illustrates a cross sectional view along cut line II-II′ illustrating the arrangement of dielectric 1110, bit line contact 1130, source/drain area 1140 and intrinsic layer 1150.

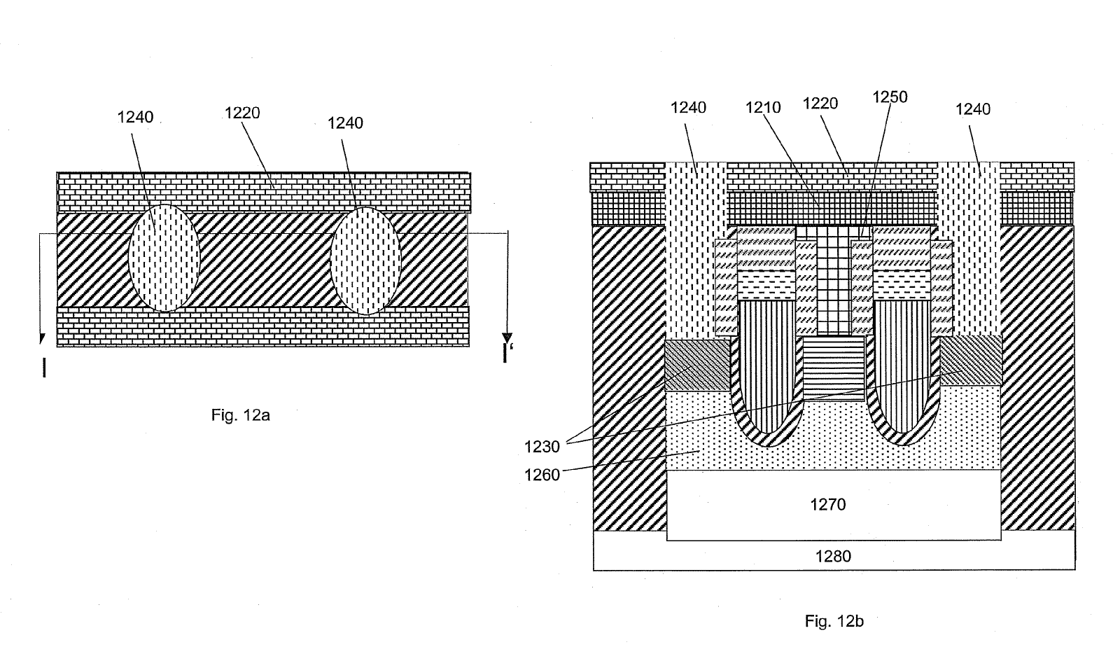

FIG. 12 illustrate a processing stage after bit line 1210, its insulating cap 1220, source/drain regions 1230 and cell node contacts 1240 have been produced, wherein FIG. 12a illustrates a top view on the chip and FIG. 12b illustrates a cross sectional view along cut line I-I′.

After planarization of bit line contact 1250 has been performed bit lines 1210 and an insulating cap 1220 is produced similar as described with reference to FIG. 8. Subsequently holes are etched for the cell node contacts 1240 using convention lithographic and etching processes. After etching source/drain areas 1230 are produced as described with reference to FIG. 8, wherein the doping profile is controlled to produce an abrupt junction between the p+ doped area and the intrinsic layer 1260. Also as described with reference to FIG. 8 the holes are filled and the cell contact material is planarized with stop on cap 1220. Reference numerals 1270 illustrate an insulating layer for insulating intrinsic layer 1260 from substrate 1280.

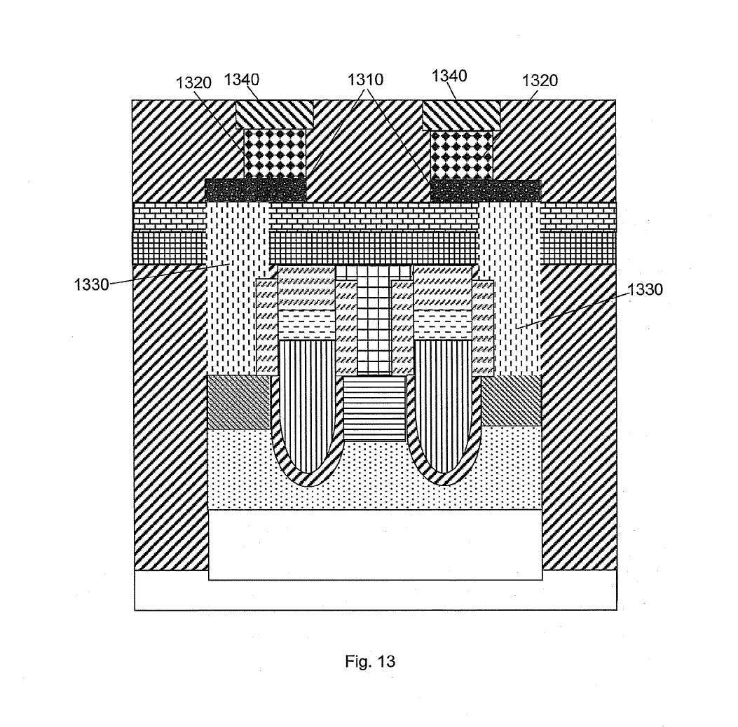

FIG. 13 illustrates a cross sectional view after having performed back end processes as described with reference to FIG. 9. In the conventional back end processing bottom electrode contacts 1310 have been produced to couple the volumes of phase change material 1320 to cell node contacts 1330 and source word lines 1340 have been produced coupling to the volume of phase change material.

Similar as mentioned with reference to the design of FIG. 9 the volumes of phase change material can be arranged in the holes of the cell node contacts, such that the holes etched for the cell node contacts are at least partially filled with phase change material. Thus source word lines may then be placed on bottom electrode contacts 1310 or directly on the phase change material.

In another embodiment the invention can be implemented with a planar tunnel field effect transistor (planar TFET), i.e. with a rectilinear current path such that the current may flow straight-lined between source and drain in both directions.

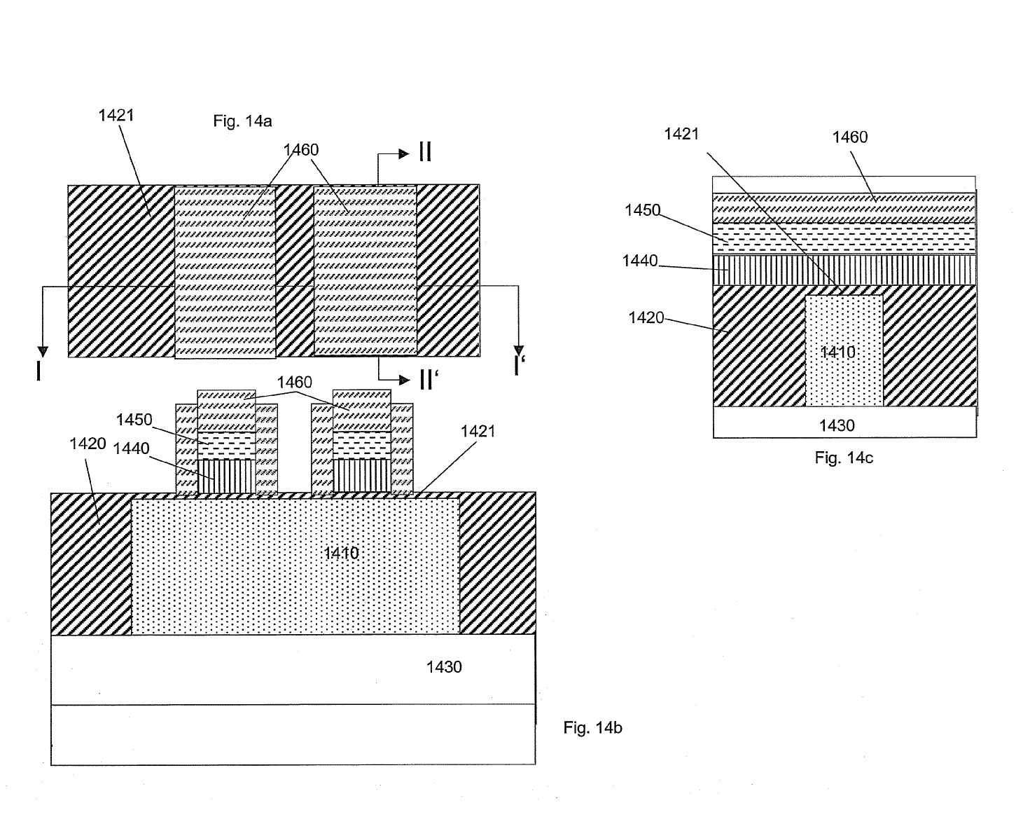

FIGS. 14a to 14c illustrate an early stage when producing the planar TFET, wherein FIG. 14a illustrates a top view on the chip and FIGS. 14b-c illustrate cross sectional views along cut lines I-I′ and II-II′ respectively. The production of the intrinsic area 1410 embedded in dielectric 1420 on a p− or n− or oxide layer 1430 or SOI is identical as described with reference to FIG. 5. Starting from here a thin layer 1421 of oxide, which forms the gate oxide, is produced at least on top of intrinsic layer 1410. Subsequently a gate conductor stack is formed on top of the gate oxide 1421, wherein various gate stack designs are possible. In this embodiment the gate stack includes a first layer 1440 of conducting material and on top of that a second layer 1450 of conducting material, wherein for example the first layer may be poly silicon and the second layer may be a metal such as tungsten, tungsten silicide or an alloy like TiN. Other architectures for example may include only one of these layers. After these layers are shaped to lines by conventional lithographic and etching processes an insulating cap 1460 of any dielectric, for example such as SiN, is produced, wherein the sidewalls of the gate conductor stack are insulated by spacers.

The following processes are identical to that described with reference to FIGS. 11, 12 and 13.

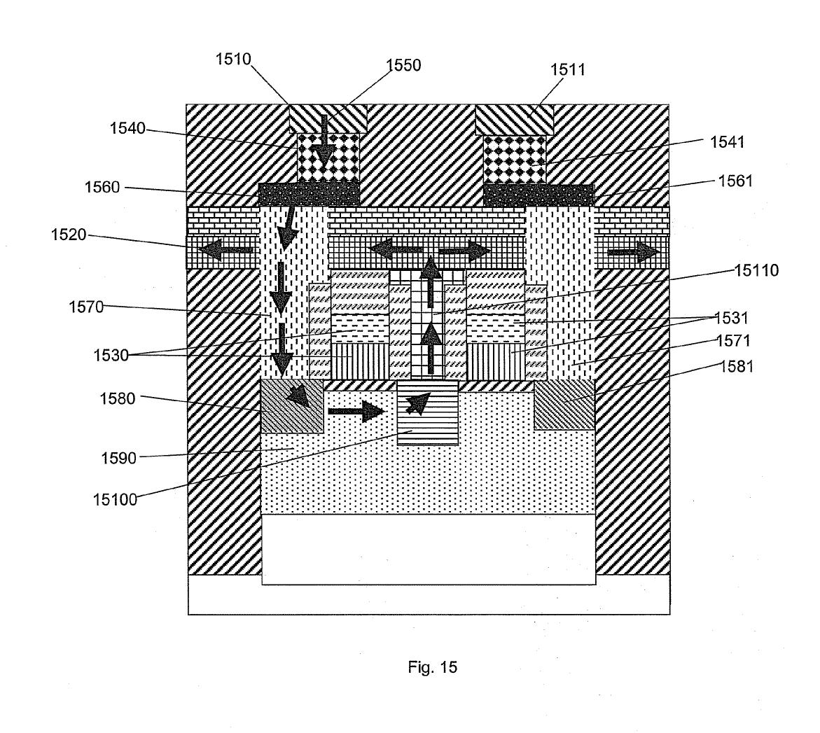

FIG. 15 illustrates a cross sectional view through two adjacent memory cells, wherein the selection transistors are planar TFETs, i.e. with planar, i.e. rectilinear current paths between source and drain.

For setting or resetting for example the PCRAM cell on the left side of the figure a setting or resetting voltage is coupled to the source wordline 1510 and a zero voltage is coupled to bit line 1520. The gate voltage applied to gate conductor line 1530, which is the gate word line, can be either 0 Volts or higher in order to effectuate a conducting tunnel increasing the conductivity of the current path. As the PIN diode of the TFET is operated in its conducting direction a current will flow from the source word line 1510 through the volume of phase change material 1540 as indicated by arrows 1550 and through bottom electrode contact 1560 to cell node contact 1570. From there the current is fed through p+ area 1580, which is the source of the PIN diode of the TFET transistor, into the intrinsic layer 1590 and to the n+ area 15100 being the shared drain of the two transistors. The current leaves drain 15100 via bit line contact 15110 and then dissipates via bit line 1520.

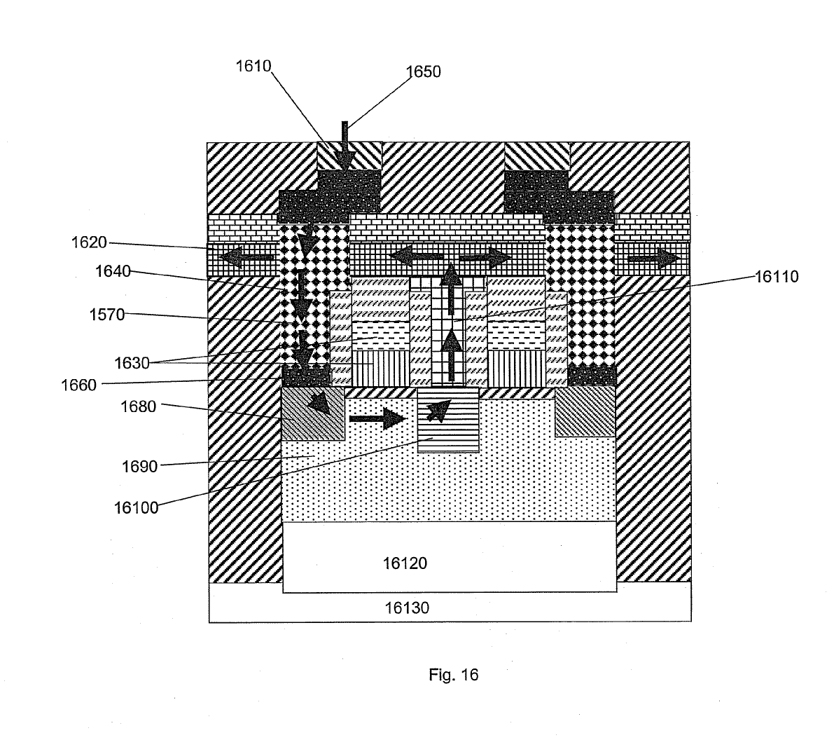

It is apparent from this embodiment and those described above that the design illustrated in FIG. 16 may also include a recessed gate conductor line, such that the current flow between source and drain is curved.

For reading the state of the cell, i.e. sensing the resistivity of phase change material 1540 a reading voltage is coupled to bit line 1520, a zero voltage is coupled to the source word line 1510 and a bias voltage is coupled to the gate conductor stack 1530, i.e. the gate word line. The applied gate voltage effectuates a tunneling current flow from drain 15100 through intrinsic layer 1590 to source 1580, such that the current direction is inversed, i.e. opposed to the direction indicated by arrows 1550. As mentioned afore this tunneling current is smaller than the current flowing when setting or resetting the cell, but still sufficient to sense the resistivity of phase change material 1540. In this way the current direction is reversed, such that the current enters the cell from bit line 1520 and is discharged via source word lines 1510.

As in this embodiment there is no hurdle in the current path, i.e. a recessed gate conductor in the intrinsic layer as illustrated in the previously described embodiments, the current path between source 1580 and shared drain 15100 is straight lined. The length of the current path in this embodiment is thus defined by the distance between the source area 1580 and the drain area 15100.

The second PCRAM cell in this embodiment substantially includes phase change material 1541 coupled to a word line 1511 and to bottom electrode contact 1561, cell node 1571 and source area 1581. Intrinsic layer 1590, shared drain 15100 as well as bit line contact 15110 are shared with the cell on the right side of the drawing.

Operating the cell on the left side will leave the cell on the right hand side unaffected, because there will be no considerable current flow through its phase change material 1541. When setting or resetting the left cell and the voltage applied to gate word line 1541 is at 0 Volts, then the PIN diode of the right cell is operated in its blocking direction, such that there will be only a negligible leakage current. As a gate voltage of 0 Volts is applied to gate conductor 1531 when reading the left cell, there will be no tunneling effect to source 1581, so that also in this case there will be only a negligible leakage current.

FIG. 16 illustrates a variation of the design, wherein the phase change material, i.e. the memory element, is arranged in the space of the cell node contacts 1570. When setting or resetting the cell a setting or resetting voltage is applied to source word line 1610 and a zero voltage is applied to bit line 1620. A gate voltage Vbias, which may be a zero voltage or higher, may be applied to gate conductor line 1630, which is the gate word line. A current as indicated by arrows 1650 flows from the source word line 1610 through the volume of phase change material 1640, bottom electrode contact 1660 to the p+ area, i.e. the source of the TFET transistor, and through intrinsic material 1690 to the n+ doped area 16100, which is the shared drain area of the two transistors. An insulating layer 16120 insulates the intrinsic material 1690 from substrate 16130. The current then leaves the drain 16100 via bit line contact 16110 and dissipates via bit line 1620.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a memory cell, and
a selection transistor for selecting the memory cell, wherein the selection transistor is a tunnel field effect transistor.

2. The integrated circuit of claim 1, wherein the tunnel field effect transistor comprises:
a source region;
a drain region; and
an intrinsically conducting region connecting the source and drain region.

3. The integrated circuit of claim 2, comprising wherein the intrinsically conducting region is arranged underneath the source and drain region, and wherein the tunnel field effect transistor further comprises a recess separating the source and drain region and extending vertically into the intrinsically conducting region.

4. The integrated circuit of claim 3, comprising wherein the recess has a rounded shape at the recess bottom.

5. The integrated circuit of claim 3, comprising wherein the recess in the intrinsically conducting region at least partially takes the gate conductor of the tunnel field effect transistor.

6. The integrated circuit of claim 5, comprising wherein the recess in the intrinsically conducting region completely takes the gate conductor.

7. The integrated circuit of claim 1 comprising at least a first and a second selection transistor, wherein the first and second selection transistor share one drain region.

8. The integrated circuit of claim 1, comprising wherein the surface of the original substrate forms a reference plane, and wherein the gate conductor line of the selection transistor extends below the reference plane.

9. The integrated circuit of claim 8, comprising wherein the gate conductor line is buried below the reference plane.

10. The integrated circuit of claim 1, comprising wherein the source region of the tunnel field effect transistor is coupled to a source word line via a memory element, the gate conductor of the tunnel field effect transistor forms part of a gate word line running parallel to the source word line, and wherein the drain region of the tunnel field effect transistor is coupled to a bit line.

11. The integrated circuit of claim 1, wherein the memory cell comprises a volume of phase change material as memory element.

12. An integrated circuit comprising:
at least one pair of tunnel field effect selection transistors formed in a substrate configured for selecting resistively switching memory cells, comprising:
a first and a second source/drain region;
one shared drain/source region between the first and second source/drain region;
a first and a second intrinsically conducting region coupling the first source/drain region and the second source/drain region respectively to the one shared drain/source region; and
a first and second gate conductor line, the first gate conductor line arranged between the first source/drain and the one shared drain/source region and the second gate conductor line arranged between the second source/drain region and the one shared drain/source region.

13. The integrated circuit of claim 12, comprising wherein the first and second source/drain regions are p+ doped having a first transition region to the adjoining intrinsically conducting region, and the shared drain/source region is n+ doped having a second transition region to the adjoining intrinsically conducting region, wherein the width of the first transition region is smaller than the width of the second transition region.

14. The integrated circuit of claim 12, comprising wherein the surface of the original substrate forms a reference plane, and wherein the intrinsically conducting regions are arranged underneath the source and drain region, an wherein the tunnel field effect transistors each further comprise a recess separating the source and drain regions and extending vertically into the intrinsically conducting region.

15. The integrated circuit of claim 14, comprising wherein a recess fully takes a gate conductor line.

16. The integrated circuit of claim 14, wherein the gate conductor line comprises a first conducting layer located substantially below the reference plane and extending into the recess and a second conducting layer located substantially above the reference plane.

17. The integrated circuit of claim 16, wherein the first conducting layer comprises poly silicon and the second conducting layer comprises one of a metal or an alloy.

18. The integrated circuit of claim 12, comprising wherein the first source/drain region is coupled to a first source word line, the second source/drain region is coupled to a second source word line, the first gate conductor line is coupled to first gate word line, the second gate conductor line is coupled to a second gate word line and the shared drain/source region is coupled to a shared bit line.

19. The integrated circuit of claim 18, comprising wherein the word lines are parallel and the bit line is arranged perpendicular to the word lines.

20. The integrated circuit of claim 12, comprising wherein first and second gate conductor lines are arranged above the reference plane.

21. The integrated circuit of claim 12, wherein the resistively switching memory cell comprises a volume of phase change material as memory element.

22. A method of operating an integrated circuit including selecting one of a plurality of memory cells for writing, comprising:
providing memory cells comprising tunnel field effect transistors as selection transistors;
coupling the source of a tunnel field effect transistor to a source word line and the gate of the tunnel field effect transistor coupled to a gate word line; and
applying a write voltage to the source word line of the selected transistor, while a lower voltage is applied to the gate word line of the selected tunnel field effect transistor.

23. The method of claim 22, comprising applying a bias voltage to the gate word line of the selected transistor.

24. A method of claim 22 comprising:
wherein each of the memory cells comprises a tunnel field effect transistor as selection transistor, the source of the tunnel field effect transistor coupled to a source word line and the gate of the tunnel field effect transistor coupled to a gate word line, and wherein a read voltage is applied to the shared bit line and a bias voltage is applied to the gate word line of the selected tunnel field effect transistor.

25. A method of manufacturing an integrated circuit comprising selection transistors for selecting resistively switching memory cells, wherein the selection transistors are formed on a substrate and the surface of the original substrate defines a reference plane, the method comprising:
forming a region of intrinsically conducting material bordered by isolation trenches;
forming a first and a second parallel gate conductor line crossing the intrinsically conducting region;
forming an drain/source of a first conductivity type coupled to the intrinsically conducting region and extending from the surface of reference plane into it and located between the gate conductor lines;
forming a bit line coupled to the drain/source region of the first conductivity type;
forming a first and a second source/drain of a second conductivity type region coupled to the intrinsically conducting region and located outside of the gate conductor lines; and
forming a first and a second volume of resistively switching material coupled to the first or the second doped source/drain region of the second conductivity type respectively.

26. The method of claim 25, comprising wherein the first conductivity type is n+ and the second conductivity type is p+.

27. The method of claim 25, comprising wherein forming the n+ doped drain/source regions is adapted to produce a doping profile with a soft junction to the intrinsically conducting region.

28. The method of claim 25, comprising wherein forming the p+ doped source/drain regions is adapted to produce a profile with an abrupt doping borderline to the intrinsically conducting region.

29. The method of claim 25, comprising wherein forming the gate conductor lines comprises etching trenches into the intrinsically conducting region, wherein the trenches extend deeper into the intrinsically conducting region than the p+ doped source/drain regions and the n+ doped drain/source regions.

30. The method of claim 29, comprising rounding the bottom of the trenches after the first etching.

31. The method of claim 29, further comprising filling the trenches partially with a conducting material, such that these are buried below the reference plane.

32. The method of claim 29, further comprising:
placing a first conducting layer in the trenches; and
placing a second conducting layer on the first conducting layer, wherein the second conducting layer is located above the reference plane.

33. The method of claim 25, wherein the forming of the first and second p+ doped source drain regions comprises the subprocesses of etching holes at the locations of p+ doped regions into an interlayer dielectric, wherein the holes extend to the intrinsically conducting region, and p+ doping by a high dose ion implant through the holes to form the p+ doped regions.

34. The method of claim 33, further comprising filling the holes with a conducting material for coupling to the volumes of resistively switching material.

35. The method of claim 33, wherein forming the volumes of resistively switching material further comprises:
partially filling the holes with a conducting material to form bottom electrode contacts of the volumes of resistively switching material; and
filling resistively switching material into the holes and on top of the bottom electrode contacts.

36. The method of claim 35, comprising wherein the resistively switching material is a phase change material.
